(19) United States
(12) Patent Application Publication
(10) Pub. No.: US 2019/0334518 A1
(43) Pub. Date: Oct. 31, 2019

(54) UNIVERSAL SEMICONDUCTOR SWITCH

(71) Applicant: CENTUM ELECTRONICS LIMITED, Bangalore (IN)

(72) Inventors: Bhoopendrakumar SINGH, Bangalore (IN); Praveen PRADEEP KUMAR, Bangalore (IN); Vinod CHIPPALKATTI, Bangalore (IN); Kanthimathinathan THIRUGNANAM, Bangalore (IN); Aravind BHAT, Bangalore (IN)

(21) Appl. No.: 16/475,144

(22) PCT Filed: Dec. 15, 2017
(86) PCT No.: PCT/IN2017/050594

§ 371 Date: Jul. 1, 2019

(30) Foreign Application Priority Data
Dec. 31, 2016 (CN) 201641045194

(51) Int. Cl. H03K 17/16; H03K 17/081; H03K 17/60; H03K 17/567; H03K 17/687

(52) U.S. Cl. CPC H03K 17/162; H03K 17/08104; H03K 17/687; H03K 17/567; H03K 17/60

(57) ABSTRACT

The invention provides a universal semiconductor switch. The universal semiconductor switch includes a switching arrangement having an input and an output, at least one trigger circuit operably coupled to the switching arrangement and a noise immunity circuit coupled to the trigger circuit.

### FIELD OF INVENTION

The invention generally relates to the field of electronic switches and particularly to a universal semiconductor switch.

### BACKGROUND

Electronic switch is a device that can switch an electrical circuit, interrupting the current or diverting it from one conductor to another. Examples of electronic switch include but are not limited to electromechanical relays and Solid State Relays. Electromechanical relays operate on the principle of a coil of wire that becomes a temporary magnet when electricity flows through it which enables the electromechanical relays to turn ON or OFF. One physical disadvantage of the electromechanical relays is the relay being bulky and heavy. Other disadvantages of electromechanical relays include but are not limited include high failure rate due to wearable parts, slower switching, generate electromagnetic noise and interference on power lines, solid state relays are sensitive to corrosion, oxidation. The Solid State Relay generates electromagnetic noise and interference on power lines and there is no noise immunity for the ON & OFF Command signals. One disadvantage poor anti-interference ability, resistance to radiation is also poor, low reliability and reverse leakage current. Yet another system known in the art provides a solid state power controller for switching power on and off to an electrical load. The controller limits the load current to a selected maximum level by controlling the drain-source resistance of power MOSFETs used for switching the power. The disadvantages of the controller are power loss in the MOSFET, which in turn leads to the failure of the controller and a complex circuitry. The circuit is complex. The circuit is not capable to limit the input plug-in inrush current by controlling the GATE to Source voltage of MOSFET. The loss in the MOSFET is high. The prevention for false triggering of the circuit is not possible.

Therefore, there is a need for a universal semiconductor switch that can be adapted for various modes of operation without the need to replace the switch.

### BRIEF DESCRIPTION OF DRAWINGS

So that the manner in which the recited features of the invention can be understood in detail, some of the embodiments are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a block diagram of a universal semiconductor switch, according to an embodiment of the invention.

FIG. 2 shows a circuit layout of the components of the universal semiconductor switch, according to an embodiment of the invention.

### SUMMARY OF THE INVENTION

One aspect of the invention provides a universal semiconductor switch. The universal semiconductor switch includes a switching arrangement having an input and an output. A trigger circuit is operably coupled to the switching arrangement. A noise immunity circuit coupled to the trigger circuit.

### DETAILED DESCRIPTION OF THE INVENTION

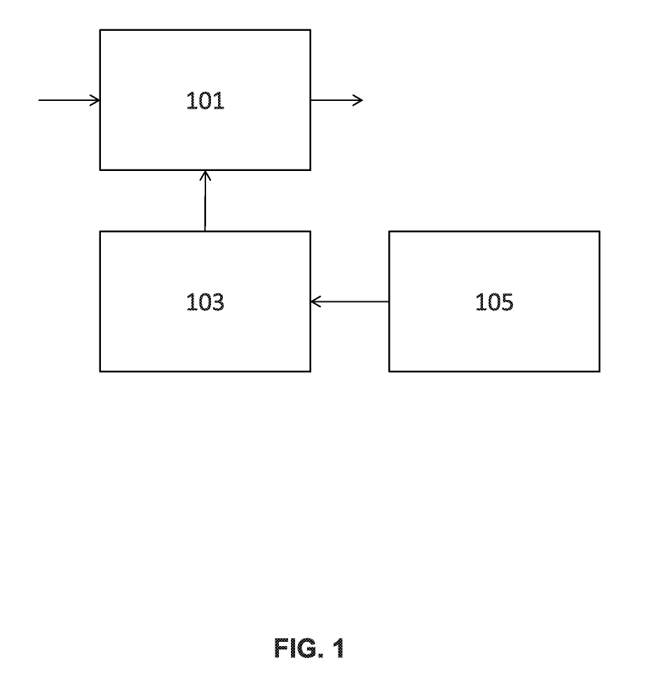

Various embodiments of the invention provide a universal semiconductor switch. FIG. 1 shows a block diagram of a universal semiconductor switch, according to an embodiment of the invention. The universal semiconductor switch includes a switching arrangement 101 having an input and an output, a trigger circuit 103, noise immunity circuit 105 operably coupled to the switching arrangement 101. The switching arrangement 101 switches the input power. The trigger circuit 103 is used to trigger the switching arrangement 101. The noise immunity circuit 105 is used to filter out the unwanted signals.

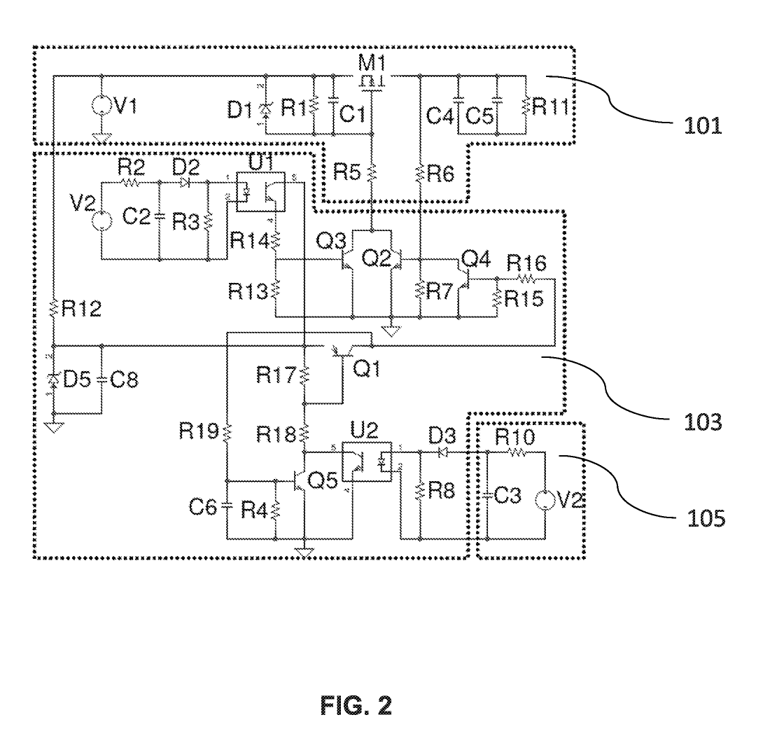

FIG. 2 shows a circuit layout of the components of the universal semiconductor switch, according to an embodiment of the invention. The universal switch includes a switching arrangement 101. The switching arrangement 101 includes a solid state switching device. The solid state switching device described herein includes but is not limited to MOSFET, BJT, IGBT, and/or combinations thereof. In one example of the invention, the means for switching is through a MOSFET M1. The solid state switching device is connected to a source of power. The source of power is configured as the input for switching the solid state device. The solid state switching device is operably coupled to a current limiting arrangement. The current limiting arrangement provides the limit of the current to the load. The current limiting arrangement includes but is not limited to passive circuit elements. Examples of passive circuit elements include but are not limited to NTC, resistor, capacitor, and/or combinations thereof. In one example of the invention, the current limiting arrangement is a combination of a resistor and a capacitor. At the output of the solid state switching device a filter circuit is connected. Examples of filter circuit include but are not limited to a capacitor filter, a LC filter, a RC filter and/or combinations thereof. In one example of the invention, the filter circuit is a RC filter.

A trigger circuit 103 is connected to the switching arrangement 101. The trigger circuit 103 includes a coupling arrangement. The coupling arrangement includes a coupler. Further, the coupler can include isolated components or non-isolated components. Examples of isolated components include but are not limited to a transistor opto-isolator, a diode opto-isolator, a resistive opto-isolator, and/or combinations thereof. Examples of non isolated components include but are not limited to a transistor, BJT, MOSFET, IGBT and/or combinations thereof.

The coupling arrangement also includes a noise immunity circuit. Examples of noise immunity circuit includes but is not limited to a low pass filter, a band pass filter, a band select filter and/or combinations thereof. In one example of the invention, the noise immunity circuit includes a low pass filter. A plurality of power sources are connected to the coupling arrangement. Examples of power source includes but is not limited to pulse generator, pulsating power sources, signal generators, pulse timers, digital pulse signals and/or combination thereof. The power source is connected to the coupler through the noise immunity circuit.

The trigger circuit further includes a latch arrangement. The latch arrangement includes a voltage divider network. Examples of voltage divider network include but are not limited to a resistive voltage divider network, a capacitive voltage divider network and/or combinations thereof. In one example of the invention, the voltage divider network is a resistive voltage divider. The voltage divider network is connected to a plurality of semiconductor switching components. Examples of semiconductor switching components include but are not limited to a transistor, a MOSFET, a BJT, an IGBT, and/or combinations thereof. In one example of the invention, the plurality of semiconductor switching components is transistors. The latch arrangement also includes a plurality of passive components. Examples of passive components include but are not limited to a resistor, a capacitor, and/or combinations thereof. In one example of the invention, the passive components are at least one combination of the resistor and the capacitor.

Working of the Circuit:

In one example of the invention, the universal switch as described herein above is operated by providing the input to the source terminal of M1. The trigger circuits are selectively powered. In one example, one of the trigger circuits is powered ON and the other trigger circuit is powered OFF. The selective triggering of the trigger circuit enables the M1 to start turning ON. The turning ON of the M1 yields an output across the filter circuit. The turning ON of the M1 of the switching arrangement further activates the current limiting arrangement. The current limiting arrangement is configured for restricting the in-rush current to a pre-determined value. The value of the current is dependent on the operating conditions of the switch.

The universal switch as explained herein above can be configured to perform in a plurality of modes. Examples of mode of performance include at least one of an isolated non latch switch, an isolated latch switch, a non isolated latch switch or a non isolated non latch switch. Each of the modes of performance shall be explained in detail as exemplary examples.

### Example 1: Isolated Non-Latch Switch with Plug-in in-Rush

The isolated non-latch switch with plug-in in-rush is achieved by selectively operating the latch arrangement of the trigger circuit. The non latch mode is derived by excluding the voltage divider of the latch arrangement. The exclusion of the voltage divider turns OFF the latch arrangement. The turning OFF of the latch arrangement of the trigger circuit enables operation of the universal switch through the other trigger circuit. However, the output of the universal switch is unaltered by the non-latch condition. Further, the signal delivered to M1 in the non-latch mode of the universal switch can be filtered through the noise immunity circuit.

### Example 2: Isolated Non Latch Switch without Plug-in in-Rush Current

The non latch mode of the switch is obtained in a manner as explained herein above. Further, the exclusion of the current limiting arrangement does not limit the input current to a pre-determined value. Further, the signal delivered to M1 in the non-latch mode of the universal switch can be filtered through the noise immunity circuit.

### Example 3: Isolated Latch Type Switch without Plug-in in-Rush Current Limiting and Noise Immunity

The isolated latch switch without plug-in in rush is achieved by operating the latch arrangement of the trigger circuit without the current limiting arrangement. The latch mode is derived by including the voltage divider of the latch arrangement. The inclusion of the voltage divider turns ON the latch arrangement. However, the output of the universal switch is unaltered by the latch condition. Further, the signal delivered to M1 in the non-latch mode of the universal switch can be filtered through the noise immunity circuit.

### Example 4: Isolated Latch Type Switch without Noise Immunity

The isolated latch switch with plug-in in rush is achieved by operating the latch arrangement of the trigger circuit without the noise immunity circuit. The operation of the universal switch in the latch mode is as described herein above.

### Example 5: Non-Isolated Latch Switch with Plug-in in-Rush Current Limiting and Noise Immunity

The non-isolated latch switch with plug-in in rush is achieved by selecting a non-isolated transistor in the coupler arrangement of the latch arrangement of the trigger circuit. Further, the switch is operated with the noise immunity circuit and the current limiting arrangement. The operation of the universal switch in the latch mode with the noise immunity circuit and the current limiting arrangement is as described herein above.

### Example 6: Non-Isolated Latch Switch without Plug-in in-Rush Current Limiting and Noise Immunity

The universal semiconductor switch as a non-isolated latch type switch without noise immunity. The isolated latch switch without plug-in in-rush is achieved by operating the latch arrangement of the trigger circuit with the noise immunity circuit. The operation of the universal switch in the latch mode is as described herein above.

### Example 7: Non-Isolated Non-Latch Type with Plug-in in-Rush Current Limiting and Noise Immunity

The universal semiconductor switch as a non-isolated non-latch type switch with noise immunity. The non-isolated latch switch with plug-in in-rush is achieved by operating the latch arrangement of the trigger circuit with the noise immunity circuit. The operation of the universal switch in the latch mode is as described herein above.

### Example 8: Non-Isolated Non-Latch Type without Plug-in in-Rush Current Limiting and Noise Immunity

The universal semiconductor switch as a non-isolated non-latch type switch with noise immunity. The non-isolated latch switch with plug-in in-rush is achieved by operating the latch arrangement of the trigger circuit with the noise immunity circuit. The operation of the universal switch in the latch mode is as described herein above.

The invention provides a universal semiconductor switch that is capable of operating in various modes. The semiconductor switch as described herein and as illustrated through the accompanying drawings can be used to switch the DC voltage signals.

The foregoing description of the invention has been set merely to illustrate the invention and is not intended to be limiting. Since modifications of the disclosed embodiments incorporating the spirit and substance of the invention may occur to person skilled in the art, the invention should be construed to include everything within the scope of the appended claims and equivalents thereof.

We claim:

1. A universal semiconductor switch comprising of:
a switching arrangement having an input and an output;
at least one trigger circuit operably coupled to the switching arrangement; and
a noise immunity circuit coupled to the trigger circuit.

2. The switch of claim 1, wherein the switching arrangement comprises of:
at least one solid state switching device;
at least one source of power connecting to the solid state switching device;
a current limiting arrangement operably coupled to the solid state switching device; and
a filter circuit.

3. The switch of claim 2, wherein the solid state switching device is selected from the group comprising of at least one of a MOSFET, a BJT, an IGBT, a TRIAC, a TRIODE and/or combinations thereof.

4. The switch of claim 2, wherein at least one current limiting arrangement is selected from the group comprising of at least one of an NTC, a resistor, a capacitor, and/or combinations thereof.

5. The switch of claim 1, wherein the trigger circuit comprises of:
a coupling arrangement;
at least one source of power connecting to the coupling arrangement; and
a latch arrangement.

6. The coupling arrangement of claim 5, wherein the arrangement comprises of a coupler.

7. The coupler of claim 6, wherein the coupler is selected from a group comprising of a transistor opto-isolator, a diode opto-isolator, a resistive opto-isolator, an opto-isolated SCR, an opto-isolated triac, a transistor, a triac, a BJT, a MOSFET, a IGBT and/or combinations thereof.

8. The coupling arrangement of claim 1, wherein the noise immunity circuit is selected from a group comprising of a low pass filter, a band pass filter, a band select filter and/or combinations thereof.

9. The latch arrangement of claim 5, wherein the arrangement comprises of:
a voltage divider network;
plurality of semiconductor switching components; and
a plurality of passive components.

10. The latch arrangement of claim 5, wherein the voltage divider network is selected from the group comprising of a resistive voltage divider network, a capacitive voltage divider network, and/or combinations thereof.

11. The latch arrangement of claim 5, wherein the plurality of semiconductor switching component is selected from the group comprising of a transistor, a MOSFET, a BJT, an IGBT, a TRIAC, a TRIODE and/or combinations thereof.

12. The latch arrangement of claim 5, wherein passive component is selected from the group comprising of a resistor, a capacitor, an inductor, a connector, a diode and/or combinations thereof.

13. The switch of claim 1, wherein at least one noise immunity circuit is selected from the group comprising of a capacitor filter, an inductor filter, a LC filter, an RC filter and/or combinations thereof.

14. The switch of claim 1, wherein the switch is configured to perform as at least one of an isolated non latch switch, an isolated latch switch, a non isolated latch switch or an non isolated non latch switch.
